(19) United States
(12) Patent Application Publication
(10) Pub. No.: US 2025/0383962 A1
(43) Pub. Date: Dec. 18, 2025

(54) FLASH MEMORY SCHEME CAPABLE OF DETECTING ERRORS OCCURRING IN SET-FEATURE AND GET-FEATURE OPERATIONS WHEN SIGNAL QUALITY IS POOR

(71) Applicant: Silicon Motion, Inc., Hsinchu County (TW)

(72) Inventors: Tsu-Han Lu, Hsinchu City (TW); Hsiao-Chang Yen, Hsinchu County (TW)

(73) Assignee: Silicon Motion, Inc., Hsinchu County (TW)

(21) Appl. No.: 18/948,552

(22) Filed: Nov. 15, 2024

(30) Foreign Application Priority Data
Jun. 18, 2024 (TW) 113122485

(51) Int. Cl. G06F 11/10

(52) U.S. Cl. CPC G06F 11/1068; G06F 11/1012; G06F 11/1048

(57) ABSTRACT

A method of flash memory controller includes: activating configuration of feature address of set-feature operation for a flash memory device; performing specific error correction protection operation upon multiple bits of parameter data corresponding to the set-feature operation to generate at least one check bit; generating and transmitting set-feature signal to the flash memory device to make the flash memory device determine whether errors occur in the parameter data or not based on the at least one check bit, the set-feature signal sequentially including a set-feature command, the feature address, the multiple bits of the parameter data, and the at least one check bit, the parameter data and the at least one check bit forming multiple bytes following the feature address; and, polling a status register of the flash memory device to get a result bit from the status register to know whether an error occurs in the transmitted set-feature signal.

### BACKGROUND OF THE INVENTION

### 1. Field Of The Invention

The present invention relates to a flash memory scheme, and more particularly to a flash memory controller, a method used in a flash memory controller, and a flash memory device.

### 2. Description Of The Prior Art

Generally speaking, a flash memory device coupled to a flash memory controller will perform a get-feature operation to return/report the current parameters of the flash memory device into the flash memory controller after completing the set-feature operation. If the reported parameters are the same and consistent with the parameters set by the set-feature operation, this indicates that the result of the set-feature operation is successful. However, when the quality of the transmission signal between the flash memory controller and the flash memory device is poor and the transmission signal is associated with the operation of the feature address, if the configurations between the flash memory controller and flash memory device are different, then this causes that signal transmission and reception fails. For example, if a conventional flash memory controller wants to change the transmission mode from mode A to mode B, the conventional flash memory controller at first performs a set-feature operation in the mode A, then changes the conventional flash memory controller from the mode A to the mode B, and then performs a get-feature operation in the mode B to control the conventional flash memory device to return/report parameters and checks whether the returned parameters are correct and consistent with the configured parameters. However, if the signal quality is too poor at this time and the mode of the conventional flash memory device does not change from the mode A to the mode B (i.e. remains in the mode A) while the conventional flash memory controller is performing the get-feature operation still in the mode B, then this may cause unexpected errors.

### SUMMARY OF THE INVENTION

Therefore one of objectives of the present invention is to provide a flash memory controller, a flash memory device, and a corresponding method to solve the above problems.

According to embodiments of the present invention, a flash memory controller is disclosed. The flash memory controller is coupled to a flash memory device through a specific communication interface, and it comprises an input/output circuit and a processor. The input/output circuit is coupled to the flash memory device through the specific communication interface. The processor is coupled to the input/output circuit and used for: activating a configuration of a feature address of a set-feature operation of the flash memory device; performing a specific error correction protection operation upon multiple bits of a parameter data corresponding to the set-feature operation to generate at least one check bit; and, controlling the input/output circuit to generate and transmit a set-feature signal to the flash memory device; the set-feature signal sequentially comprising a set-feature command, the feature address, the multiple bits of the parameter data, and the at least one check bit, so as to make the flash memory device determine whether an error occurs in the multiple bits of the parameter data according to the at least one check bit to generate a detection result bit, the multiple bits of the parameter data and the at least one check bit forming multiple bytes following the feature address. The processor further polls a status register of the flash memory device through the input/output circuit to obtain the detection result bit temporarily stored in the status register to determine whether an error occurs in an operation corresponding to the transmitted set-feature signal.

According to the embodiments, a method of a flash memory controller coupled to a flash memory device through a specific communication interface is disclosed. The method comprises: activating a configuration of a feature address of a set-feature operation of the flash memory device; performing a specific error correction protection operation upon multiple bits of a parameter data corresponding to the set-feature operation to generate at least one check bit; generating and transmitting a set-feature signal to the flash memory device, the set-feature signal sequentially comprising a set-feature command, the feature address, the multiple bits of the parameter data, and the at least one check bit, to make the flash memory device determine whether an error occurs in the multiple bits of the parameter data according to the at least one check bit to generate a detection result bit, the multiple bits of the parameter data and the at least one check bit forming multiple bytes following the feature address; and, polling a status register of the flash memory device to obtain the detection result bit temporarily stored in the status register to determine whether an error occurs in an operation corresponding to the transmitted set-feature signal.

According to the embodiments, a flash memory device is disclosed. The flash memory device is coupled to a flash memory controller through a specific communication interface, and it comprises an input/output control circuit, a command register, an address register, a memory cell array, at least one address decoder, a voltage generator, a control circuit, and a status register. The input/output control circuit is coupled to the flash memory controller through the specific communication interface. The command register, coupled to the input/output control circuit, is used for buffering command information sent from the flash memory controller and transmitted through the input/output control circuit. The address register, coupled to the input/output control circuit, is used for buffering address information sent by the flash memory controller and transmitted through the input/output control circuit. The memory cell array has a plurality of flash memory chips, and each flash memory chip has a plurality of flash memory planes. Each flash memory plane has a plurality of storage blocks, and each storage block has a plurality of multiple storage pages. The at least one address decoder is coupled to the memory cell array. The voltage generator, coupled between the at least one address decoder and the memory cell array, is used for generating and outputting at least one threshold voltage level to the at least one address decoder. The control circuit, coupled to the address register, the command register, the voltage generator, and the memory cell array, is used for controlling the voltage generator to control the at least one address decoder to access a storage block of a flash memory chip of the memory cell array according to the at least one threshold voltage level. The status register, is coupled to the input/output control circuit and the control circuit. When the flash memory device receives a set-feature signal, the control circuit is used to check and compare data of multiple bytes following a feature address of the set-feature signal to determine whether an error occurs in a set-feature operation corresponding to the set-feature signal to generate a detection result bit, and updates the detection result bit into the status register so that the flash memory controller then obtains the detection result bit by polling the status register.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a block diagram of a flash memory controller and a flash memory device in a storage device according to the embodiments of the present invention.

FIG. 2 is a schematic diagram of a flowchart of an example of an operating method of a flash memory controller corresponding to the storage device in FIG. 1.

FIG. 3 is a schematic diagram of an example of set-feature signals and get-feature signals used in an embodiment of the present invention.

FIG. 4 is a schematic diagram of an example of set-feature signals and get-feature signals used in another embodiment of the present invention.

### DETAILED DESCRIPTION

The present invention aims at providing a technical solution that can quickly know and determine whether the parameter data of a set-feature operation is correct by designing the parameter data (one or more parameters) carried in a set-feature signal sent by the flash memory controller to the flash memory device to detect whether error bits occur in the parameter data. In addition, after the execution of the set-feature operation, the flash memory device itself can detect whether the received parameter data has error bits and place a detection result in a detection result bit (i.e. a pass/fail bit) and return/report the detection result bit into the flash memory controller in the subsequent polling status.

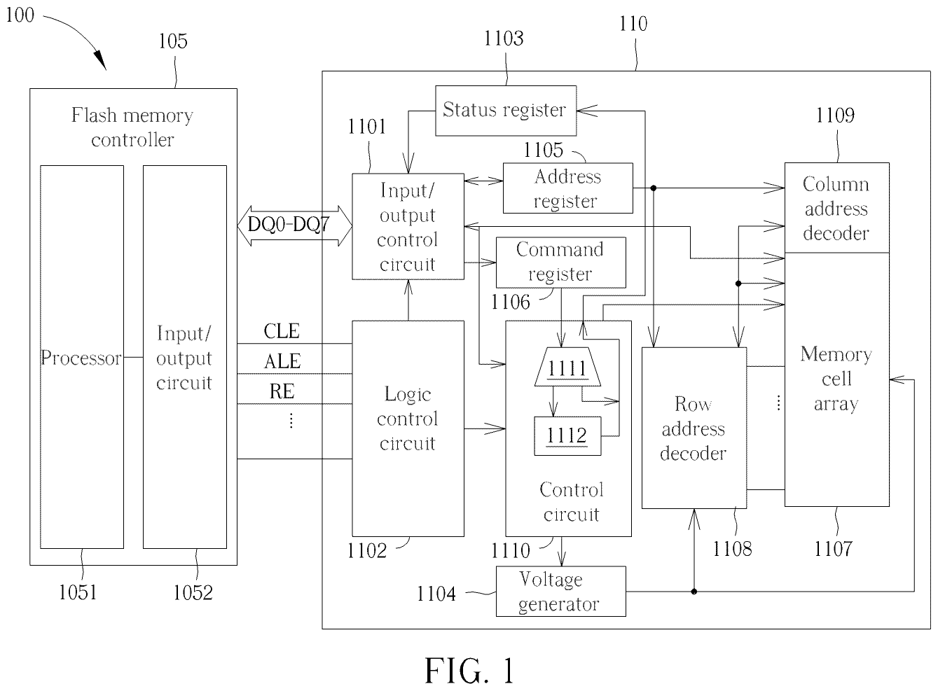

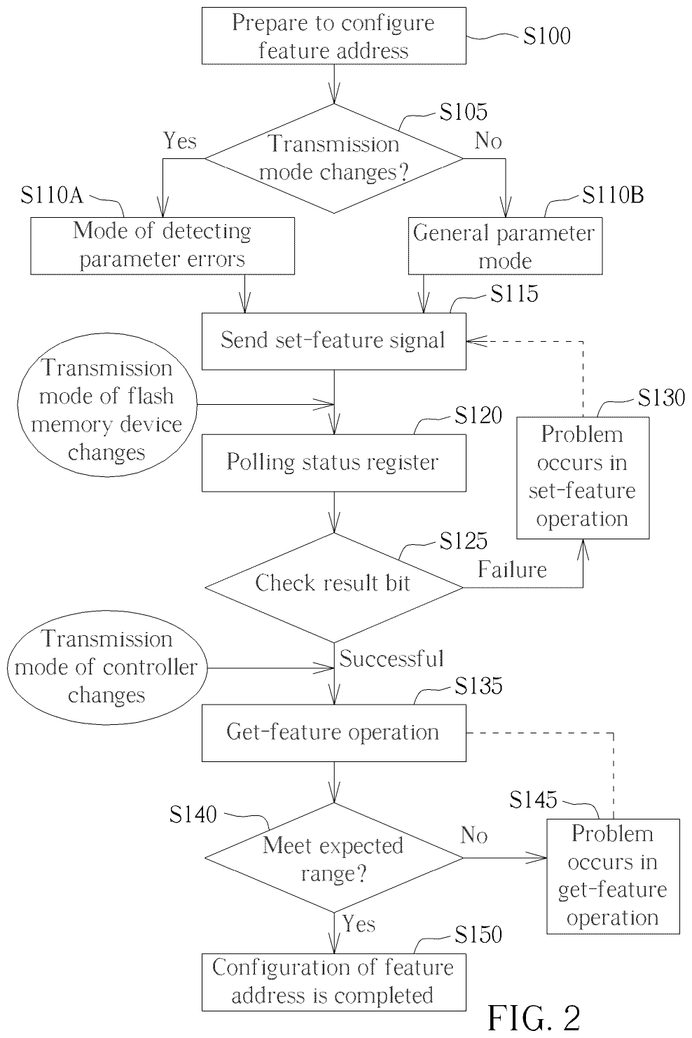

Refer to FIG. 1 in conjunction with FIG. 2. FIG. 1 is a block diagram of a flash memory controller and a flash memory device in a storage device according to the embodiments of the present invention. FIG. 2 is a schematic diagram of a flowchart of an example of an operating method of a flash memory controller 105 corresponding to the storage device 100 in FIG. 1. As shown in FIG. 1, the storage device 100 is for example a solid state drive (SSD) and includes a flash memory controller 105 and a flash memory device 110. The flash memory controller 105 is a memory controller in the solid state drive device 100, and the flash memory device 110 is a flash memory element in the solid state drive device 100 and may include for example one or more flash memory chips (or dies).

The flash memory controller 105 at least includes a processor 1051 and an input/output circuit 1052. The processor 1051 is coupled to the input/output circuit 1052 and is used to control the input/output circuit 1052 to send access (e.g. read, write/program, or erase) command signals/sequences through a specific communication interface into the flash memory device 110 to control and access the flash memory device 110. The specific communication interface includes, for example, multiple data pins DQ0-DQ7, a command latch enable pin CLE, an address latch enable pin ALE, a read enable pin RE, and so on.

The flash memory device 110 is, for example, a NAND-type flash memory device including multiple chips/dies. The flash memory device 110 includes an input/output control circuit 1101, a logic control circuit 1102, a status register 1103, a voltage generator 1104 such as a high voltage generator (but not limited), an address register 1105, a command register 1106, a memory cell array 1107, a row address decoder 1108, a column address decoder 1109, and a control circuit 1110. The input/output control circuit 1101 is coupled to the flash memory controller 105 through the specific communication interface. The command register 1106 is coupled to the input/output control circuit 1101 and is used for buffering command information sent from the flash memory controller 105 and transmitted through the input/output control circuit 1101. The address register 1105 is coupled to the input/output control circuit 1101 and is used to buffer address information sent by the flash memory controller 105 and transmitted through the input/output control circuit 1101. The at least one address decoder such as 1108 and/or 1109 is/are coupled to the memory cell array 1107. The voltage generator 1104 is coupled to the at least one address decoder such as 1108 and the memory cell array 1107, and is used to generate and output at least one threshold voltage level into the at least one address decoder such as 1108. In addition, the control circuit 1110 includes a decision circuit 1111 and a verification circuit 1112. The connection and coupling relationships of the circuit elements are shown in FIG. 1.

The processor 1051 is used to activate/initiate the configuration/setting of a feature address of a set-feature operation of the flash memory device 110, to perform a specific error correction protection operation upon multiple bits of a parameter data corresponding to the set-feature operation to generate at least one check bit, to control the input/output circuit 1052 to generate and transmit a set-feature signal into the flash memory device 110 and the set-feature signal sequentially includes a set-feature command, the feature address, the multiple bits of the parameter data, and the at least one check bit, and to make/enable the flash memory device 110 determine whether an error occurs in the multiple bits of the parameter data based on the at least one check bit to generate a detection result bit. The multiple bits of the parameter data and the at least one check bit form multiple bytes following the feature address. In addition, the processor 1051 polls the status register 1103 of the flash memory device 110 by using the input/output circuit 1052, to obtain the detection result bit temporarily stored in the status register 1103 to determine and know whether an error occurs in an operation corresponding to the sent set-feature signal.

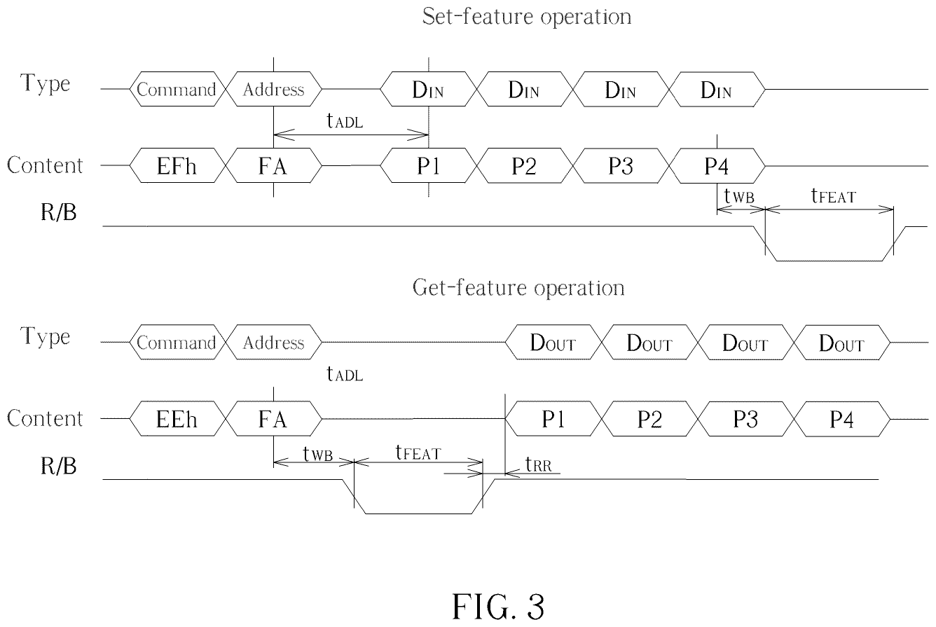

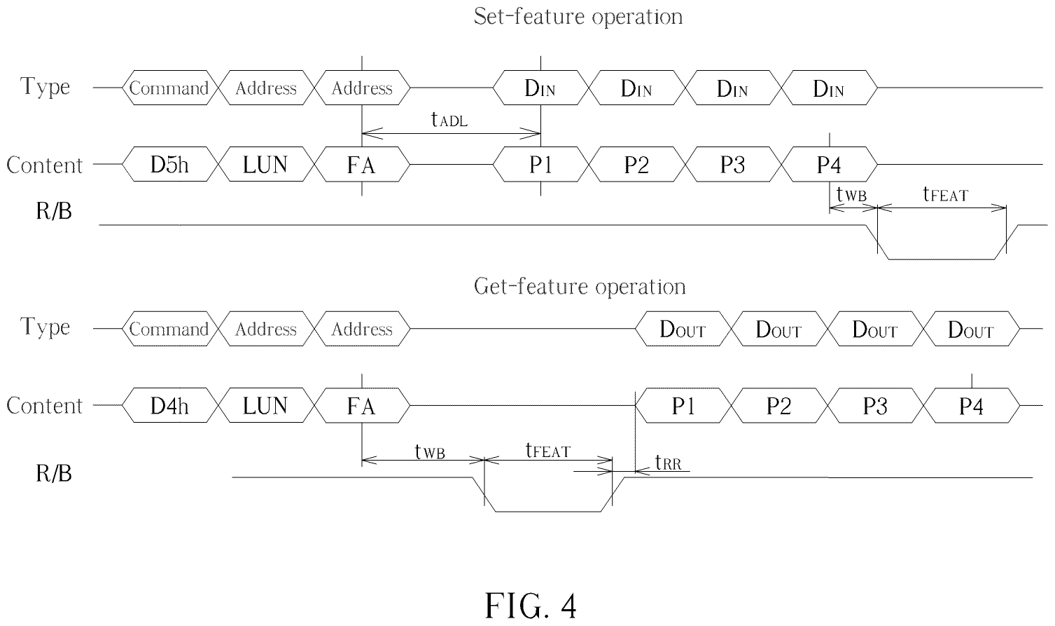

Refer to FIG. 3 in conjunction with FIG. 4. FIG. 3 and FIG. 4 are schematic diagrams of different examples of set-feature signals and get-feature signals used in different embodiments of the present invention. As shown in FIG. 3, the type of a set-feature signal sent by the flash memory controller 105 includes a feature command, a feature address, and for example four data bytes D_{IN}. The content of the feature command is for example EFh (the tailing ‘h’ indicates that the value is a hexadecimal value). The feature address is FA. The four data bytes D_{IN} are, for example, P1-P4. The R/B signal line is used by the flash memory controller 105 to monitor the operating status of the flash memory device 110. For example, when the R/B signal line is at a low level, it means that the flash memory device 110 currently is in a busy state (busy). When the R/B signal line is at a high level, it indicates that the flash memory device 110 is currently in a ready state. tADL is the time from the beginning of the address cycle to the end of the rising edge of the first data. tWB is for example the time of the high level of the previous cycle before the R/B signal line starts to be sampled. tFEAT is, for example, the time when the flash memory device 110 is in a busy state and performs a corresponding operation. tRR is, for example, the time when the flash memory device 110 leaves the busy state and then returns to the ready state. Correspondingly, in FIG. 3, the type of get-feature signal sent by the flash memory controller 105 includes a feature command and a feature address. The feature command is EEh, and the feature address is FA. The data bytes returned/reported by the flash memory device 110 are represented by D_{OUT}, e.g. P1-P4. Similarly, as shown in FIG. 4, the type of a set-feature signal sent by the flash memory controller 105 includes a feature command, a logical unit number address, a feature address, and for example four data bytes D_{IN}. The content of this feature command is, for example, D5h (the tailing “h” indicates that the value is a hexadecimal value). The logical unit number address is LUN, the feature address is FA, and four data bytes D_{IN} are, for example, P1-P4. Correspondingly, in FIG. 4, the type of get-feature signal sent by the flash memory controller 105 includes a feature command, a logical unit number address, and a feature address. The feature command is D4h, the logical unit number address is LUN, and the feature address is FA. The data bytes returned/reported by the flash memory device 110 are represented by D_{OUT}, e.g. P1-P4. Using the logical unit number address, for example, can designate a certain chip of the flash memory device 110 to perform a set-feature operation and a get-feature operation.

Before generating and transmitting the set-feature signal to the flash memory device 110, the processor 1051 of the flash memory controller 105 will at first determine whether the feature address is associated with a change of a transmission mode. If the feature address is associated with the change of the transmission mode, then the processor 1051 generates the at least one check bit to make the flash memory device 110 determine whether an error occurs in the multiple bits of the parameter data when the transmission mode changes. If the feature address is not associated with the change of the transmission mode, then the processor 1051 does not generate the at least one check bit, and the flash memory device 110 does not determine whether an error occurs in the multiple bits of the parameter data.

In addition, in one embodiment, when the result obtained by polling the detection result bit is that the set-feature operation is successful, the processor 1051 further sends a get-feature signal to the flash memory device 110 through the input/output circuit 1052 to control the flash memory device 110 to return/report the multiple bits of the parameter data corresponding to the feature address, and to determine whether an error occurs in a get-feature operation corresponding to the sent get-feature signal according to a result of whether a value indicated by the multiple bits of the reported parameter data conforms to an expected value range. In addition, in one embodiment, when the values indicated by the multiple bits of the returned/reported parameter data conforms to the expected value range, the processor 1051 determines that a get-feature operation corresponding to the get-feature signal is successful and determines that the configuration of the feature address is correctly completed at this time. When the values indicated by the multiple bits of the returned parameter data do not conform to the expected value range, the processor 1051 determines that the get-feature operation corresponding to the get-feature signal fails, and sends the get-feature signal to the flash memory device 110 again.

In addition, in one embodiment, when the result of polling the detection result bit is that the set-feature operation is successful, the processor 1051 further sends a get-feature signal to the flash memory device 110 through the input/output circuit 1052 to control the flash memory device 110 to return/report the multiple bits of the parameter data corresponding to the feature address, and determines whether an error occurs in an operation corresponding to the sent get-feature signal according to the content of at least one reversed bit of the multiple bits of the reported parameter data. When the at least one reserved bit is a default value, the processor 1051 determines that a get-feature operation corresponding to the get-feature signal is successful and determine that the configuration of the feature address is correctly completed at this time. When the at least one reserved bit is not the default value, the processor 1051 determines that the get-feature operation corresponding to the get-feature signal fails, and sends the get-feature signal to the flash memory device 110 again.

In addition, in one embodiment, the set-feature signal in a default setting sequentially includes the set-feature command, the feature address, and four data bytes. The at least one check bit is located in an end portion of the last one data byte of the four data bytes, and the multiple bytes of the parameter data are located in other data portions of the four data bytes except the end portion. For example, information followed by a set-feature command in a set-feature signal sent by the flash memory controller 105 to the flash memory device 110 sequentially includes, for example, four parameter bytes Byte0, Byte1, Byte2, and Byte3 of the parameter data, as shown in the following table:

| | | | | | | | |
|---|---|---|---|---|---|---|---|
| Bit7 | Bit6 | Bit5 | Bit4 | Bit3 | Bit2 | Bit1 | Bit0 |

| | |
|---|---|
| Byte0 | |
| Byte1 | |
| Byte2 | |
| Byte3 | CB |

Each of the above-mentioned bytes includes, for example, eight parameter bits. The receiving order is, for example, Bit0, Bit1, Bit2, Bit3, Bit4, Bit5, Bit6, and Bit7. The last parameter bit Bit7 of the last one parameter byte Byte3 can be for example used to store and carry a check bit CB. In other words, the last parameter bit Bit7 of the last parameter byte Byte3 is used as a check bit (rather than as a parameter bit) to detect whether an error occurs in the other parameter bits. For example, for generating the content of check bit CB, the flash memory controller 105 can use a specific error correction protection operation such as a logical operation such as exclusive-OR operation to perform the exclusive-OR operation upon all parameter bits Bit7-Bit0 of the parameter bytes Byte0, Byte1, Byte2 and the other parameter bits Bit6-Bit0 of the parameter byte Byte3 to generate a logical exclusive-OR operation result as the content of the check bit CB, and the last parameter bit Bit7 of the parameter byte Byte3 carries the content of the check bit CB.

Therefore, when the flash memory device 110 receives the parameter content of the four parameter bytes, the flash memory device 110 (such as its control circuit 1112) uses the same specific error correction protection operation (i.e. logical exclusive-OR operation) to perform the logical exclusive-OR operation upon all parameter bits Bit7-Bit0 of the received parameter bytes Byte0, Byte1, Byte2 and other parameter bits Bit6-Bito of the received parameter byte Byte3 to generate a logical exclusive-OR operation result. Then, the flash memory device 110 compares the logical exclusive-OR operation result with content of the check bit CB carried by the last parameter bit Bit7 of the received parameter byte Byte3. If the comparison result indicates that the two data are consistent (for example, both the two data are ‘0’ or both the two data are ‘1’), the flash memory device 110 determines that the result of the operation is successful, i.e. no errors occurring in an operation corresponding to a set-feature signal sent by the flash memory controller 105 to the flash memory device 110. At this time, the flash memory device 110 can generate a detection result bit PFB such as information of ‘0’, and can update the detection result bit PFB into the status register 1103 of the flash memory device 110. On the contrary, if the comparison result indicates that the two data are inconsistent, the flash memory device 110 determines that the result of the operation is a failure result, i.e. an error occurring in the operation corresponding to a set-feature signal transmitted from the flash memory controller 105 to the flash memory device 110. At this time, the flash memory device 110 can generate a detection result bit PFB such as information of ‘1’, and can update the detection result bit PFB into the status register 1103 of the flash memory device 110.

Then, after the set-feature operation is completed, the flash memory controller 105 can send a polling command to the flash memory device 110. For example, the flash memory controller 105 can check a ready bit transmitted between the flash memory controller 105 and flash memory device 110 to determine whether the set-feature operation has been completed. When the set-feature operation has been completed, the flash memory controller 105 can check the detection result bit PFB temporarily stored in the status register 11003. If the detection result bit PFB indicates a successful result, then the flash memory controller 105 can determine that the execution result of this set-feature operation is successful. On the contrary, if the detection result bit PFB indicates a failure result, then the flash memory controller 105 can determine that the execution result of this feature setting operation is a failure result. In other words, in this embodiment, the check bit is generated by the flash memory controller 105, and the flash memory device 110 itself compares the error correction protection operation result corresponding to the received parameter bit with the received check bit to determine whether the two data are consistent so as to determine whether an error occurs in the parameter data. Then, the flash memory controller 105 subsequently reads back the determination result generated by the flash memory device 110 to determine and know whether an error occurs in the previous transmitted parameter data. In addition, it should be noted that, in this embodiment, the capability for detecting whether an error occurs in the parameter data can only detect one bit error. When more than two an error bits occur, it will not be detected and corrected.

In addition, in another modification, in order to enhance the capability for detecting whether more errors occur in parameter data, a larger number of bits can be used as check bits. The set-feature signal in a default setting sequentially comprises the set-feature command, the feature address, and four data bytes. The at least one check bit indicates a check byte, and the check byte is located in the last data byte of the four data bytes. The multiple bytes of parameter data are three parameter bytes and are located in the first three data bytes of the four data bytes. The check byte is generated by the processor 1051 performing the specific error correction protection operation based on the contents of the three parameter bytes. For example, all parameter bits of the last parameter byte Byte3 in the parameter data can be used as check bits. In other words, the byte Byte3 is a check byte at this time, rather than a parameter byte. This check byte can be used to store the result of a logical exclusive-OR operation (that is, the check result) of the parameter data content of the previous three parameter bytes Byte2, Byte1 and Byte0, as shown in the following table:

| | Byte |
|---|---|
| Byte0 | |
| Byte1 | |
| Byte2 | |
| Byte3 | CB′ |

CB′ is the content of a check byte which is the result of a logical exclusive-OR operation performed by the flash memory controller upon the parameter data content of the three parameter bytes Byte2, Byte1 and Byte0. The other operation of checking and comparison are similar to the operations in the previous paragraph. In order to avoid being too lengthy, it will not be described again.

In addition, in another modification, the set-feature signal in a default setting sequentially includes the set-feature command, the feature address, and four data bytes, wherein the at least one check bit is a check byte which is appended to the end of the four data bytes to form five bytes. The multiple bytes of the parameter data are four parameter bytes and are located in the four data bytes. The check byte is generated by the processor 1051 performing the specific error correction protection operation according to the contents of the four parameter bytes. For example, information following a set-feature command in a set-feature signal sent by the flash memory controller 105 to the flash memory device 110 may sequentially include, for example, four parameter bytes Byte0, Byte1, Byte2, Byte3 of parameter data and at least one subsequent check byte, as shown in the following table:

| | Byte |
|---|---|
| Byte0 | |
| Byte1 | |
| Byte2 | |
| Byte3 | |
| Byte4 | CB′ |

Byte4 is used as a check byte, rather than a parameter byte, and can be used to store and carry the content of CB′ which is a result of a logical exclusive-OR operation performed by the flash memory controller upon the four parameter bytes Byte3, Byte2, Byte1, and Byte0 of the parameter data. The other operation of checking and comparison are similar to the operations in the previous paragraph. In order to avoid being too lengthy, it will not be described again.

In addition, in another modification, the specific error correction protection operation is not limited to a logical exclusive-OR operation, and can be other error correction code operation techniques and used to detect whether there are erroneous bits in the parameter data and to correspondingly generate one or more check bits to correct erroneous bits.

For the flash memory device 110, when the flash memory device 110 receives a set-feature signal, the control circuit 1110 is used to check and compare data of multiple bytes following a feature address of the set-feature signal to determine whether an error occurs in a set-feature operation corresponding to the set-feature signal so as to generate a detection result bit, and updates the detection result bit into the status register 1103 so that the flash memory controller 105 can subsequently obtain the detection result bit by polling the status register 1103.

For example, the decision circuit 1111 is used to receive the feature command corresponding to the set-feature operation from the command register 1106 to determine whether the feature command is associated with a change of the transmission mode. The verification circuit 1112 is coupled to the decision circuit 1111, and is used to detect and verify whether an error occurs I the data of the multiple bytes following the feature address of the set-feature signal when the feature command is associated with the change of the transmission mode. When the feature command is not associated with the change of the transmission mode, the decision circuit 1111 may output the detection result bit, which indicates a successful result, into the status register 1103. When it is determined that an error occurs in the data of the multiple bytes, the verification circuit 1112 may output the detection result bit, which indicates a failure result, into the status register 1103. When it is determined that no errors occur in the data of the multiple bytes, the verification circuit 1112 may output the detection result bit, which indicates a successful result, into the status register 1103. For example, the verification circuit 1112 is used to perform a specific error correction protection operation upon multiple parameter bits in the data of the multiple bytes to generate a result and to compare the result with at least one check bit following the multiple parameter bits to generate the detection result bit. When the result is consistent with the at least one check bit, the detection result bit generated by the verification circuit 1112 indicates a successful result. When the result is inconsistent with the at least one check bit, the detection result bit generated by the verification circuit 1112 indicates a failure result.

In addition, in another modification, the feature address carried and included in the set-feature signal only uses one portion of the subsequent four data bytes, and the bits of at least other portions are used as reserved bits such as the default value ‘0’ (but not limited). The verification circuit 1112 is used to compare the value of at least one reserved bit among the multiple parameter bits of data of the multiple bytes with a default value to update the detection result bit. When the value of the at least one reserved bit matches the default value, the detection result bit updated by the verification circuit 1112 indicates a successful result. When the value of at least one reserved bit does not match the default value, the detection result bit updated by the verification circuit 1112 indicates a failure result. For example, the flash memory device 110 may additionally check the value of the at least one reserved bit. If the value(s) of the one or more reserved bits is/are the default value “0”, then the flash memory device 110 can determine that there is no error in the operation corresponding to the received set-feature signal. In this situation, the flash memory device 110 can also generate the detection result bit PFB which is information ‘0’ (but not limited), and this detection result bit PFB is updated into the status register 1103 of the flash memory device 110. On the contrary, if one of the values of the one or more reserved bits is not the default value ‘0’, then the flash memory device 110 can determine that an error occurs in the operation corresponding to the received set-feature signal. In this situation, the flash memory device 110 can generate the detection result bit PFB which is information ‘1’, and update the detection result bit PFB into the status register 1103 of the flash memory device 110. The operation of the flash memory controller 105 to obtain the detection result bit PFB stored in the status register 1103 of the flash memory device 110 by using a polling command is the same as the operation described above and is not described again.

Furthermore, in another modification, the verification circuit 1112 can be used to determine whether at least one value specified by the multiple parameter bits of data of the multiple bytes conforms to an expected value range to update the detection result bit. When the at least one value meets the expected value range, the detection result bit updated by the verification circuit 1112 indicates a successful result. When the at least one value does not meet the expected value range, the detection result bit updated by the verification circuit 1112 indicates a failure result. For example, the feature address mentioned above is set by using four non-reserved bits in the four data bytes, and the four bits can represent a total of 16 different numerical values from 0 to 15. In one example, the configuration value of feature address may only accept the setting of a portion of the numerical range, for example, it only accepts two values 15 and 0. In other words, only 0 and 15 will be valid values, i.e. only 0 and 15 are the expected and settable parameter value range while the other parameter values are invalid values. Therefore, when receiving the parameter value included in the set-feature signal, the flash memory device 1110 can check the setting value of the parameter value to determine whether the setting value exceeds an expected settable range. When it exceeds the expected settable range, even if the values of multiple reserved bits are ‘0’, the flash memory device 110 can determine that an error occurs in the set-feature operation corresponding to the setting feature signal. In this situation, the flash memory device 110 may generate a detection result bit PFB such as information ‘1’, and updates the detection result bit PFB into the status register 1103 of the flash memory device 110. The operation of the flash memory controller 105 to obtain the detection result bit PFB stored in the status register 1103 of the flash memory device 110 by using a polling command is the same as that described above and is not described again.

In this way, by checking one or more parameter data of the set-feature signal, the flash memory can directly know or determine whether an error occurs in the set-feature operation corresponding to the set-feature signal.

As shown in FIG. 2, in step S100, the processor 1051 of the flash memory controller 105 begins and prepares to perform a specific set-feature operation, to start to configure a feature address corresponding to the specific set-feature operation. In step S105, the processor 1051 of the flash memory controller 105 determines whether the setting/configuration of the feature address will change the transmission mode. If it will change the transmission mode, the process proceeds to step S110A. On the contrary, if the setting of the feature address will not change the transmission mode, the process proceeds to step S110B. In step S110A, the processor 1051 of the flash memory controller 105 is prepared to carry a mode capable of detecting parameter errors. The mode of detecting parameter errors can detect whether there is an error in parameter data. In step S110B, the processor 1051 of the flash memory controller 105 prepares a general parameter mode. The general parameter mode cannot detect whether there is an error in the parameter data.

In step S115, the processor 1051 of the flash memory controller 105 sends a set-feature signal to the flash memory device 110 by controlling the input/output circuit 1052, and the set-feature signal sequentially includes a set-feature command, a specific feature address, and corresponding parameter data such as four or five bytes. The decision circuit 1111 determines whether the transmission mode changes. If the transmission mode changes, then the verification circuit 1112 in the control circuit of the flash memory device 110 will detect and verify whether an error occurs in the corresponding parameter data. On the contrary, if the transmission mode does not change, then the decision circuit 1111 of the flash memory device 110 will output a result that the parameter data is determined to be correct (i.e. a successful check result) into the status register 1103. Then, for example, between step S115 and step S120, the transmission signal setting (i.e. mode) of the flash memory device 110 may be changed, for example, it amy be changed in response to a change in the transmission mode. In step S120, the processor 1051 of the flash memory controller 105 performs a polling to obtain the check result stored in the status register 1103 of the flash memory device 110 when the flash memory device 110 is already in the ready state.

In step S125, the processor 1051 of the flash memory controller 105 determines that the result is a successful or failure result based on the obtained check result. If the check result indicates a failure result bit such as ‘1’, the process proceeds to Step S130, and the processor 1051 of the flash memory controller 105 can know or determine that there is a problem in the set-feature operation performed for this time. Then, the process returns to Step S115, so that the processor 1051 of the flash memory controller 105 can send the set-feature signal to the flash memory device 110 again. On the contrary, if the check result indicates a successful result bit such as ‘0’, the process proceeds to Step S135. In step S135, the processor 1051 of the flash memory controller 105 may send a get-feature signal to the flash memory device 110 to control the flash memory device 110 to return/report one or more parameter data corresponding to a set-feature operation specified by a feature address of the get-feature signal into the flash memory controller 105. In step S140, the processor 1051 of the flash memory controller 105 can also confirm whether the data content indicated by the returned parameter data meets the expected value(s), for example, whether reported parameter value is within an expected value range. If it does not meet the expected value range, then the process proceeds to Step S145, and the processor 1051 of the flash memory controller 105 may determine that there is a problem in performing the get-feature operation at this time; the process then returns to Step S135. On the contrary, if it is as expected, the process proceeds to Step S150, and the processor 1051 of the flash memory controller 105 can determine that there are no problems in executing the get-feature signal at this time, and this indicates that the execution of the corresponding set-feature operation is correct and the setting of the feature address is completed.

In other words, the flash memory controller 105 can know the check result verified by the flash memory device 110 by polling the status register 1103 of the flash memory device 110, so as to preliminarily determine whether an error occurs in the configuration of the transmitted set-feature signal. Then the flash memory controller 105 can send a get-feature signal into the flash memory device 110 to obtain the parameter data returned by the flash memory device 110 so as to determine whether the content of value indicated by the parameter data conforms to (or is within) an expected value range corresponding to the feature address. When the obtained verified check result is a successful result and the content or value indicated by the parameter data is within an expected value range, the processor 1051 of the flash memory controller 105 can determine that there are no problems and the setting of the feature address has been completed correctly. When the check result is a failure result or the content/value indicated by the parameter data does not meet an expected value range, the processor 1051 of the flash memory controller 105 can determine the a problem occurs with the setting of the feature address, and thus the setting can be configured again.

It should be noted that the operation of the verification circuit 1112 as shown in FIG. 1 is used to compare at least one check bit carried in the set-feature signal with a result of an error correction protection operation performed upon other parameter bits to generate a check result and update the check result into the status register 1103. Alternatively, the verification circuit 1112 may compare at least one reserved bit in the data bytes carried in the set-feature signal with a default reserved bit value to generate a check result and update the check result into the status register 1103. Alternatively, the verification circuit 1112 may determine whether a value specified in the data bytes carried in the feature signal conforms to an expected value range to generate a check result and update the check result into the status register 1103. All these operations are the same as those described in the previous paragraphs and are not detailed for brevity.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A flash memory controller, coupled to a flash memory device through a specific communication interface, comprising:
an input/output circuit, coupled to the flash memory device through the specific communication interface; and
a processor, coupled to the input/output circuit, for:
activating a configuration of a feature address of a set-feature operation of the flash memory device;
performing a specific error correction protection operation upon multiple bits of a parameter data corresponding to the set-feature operation to generate at least one check bit; and
controlling the input/output circuit to generate and transmit a set-feature signal to the flash memory device; the set-feature signal sequentially comprising a set-feature command, the feature address, the multiple bits of the parameter data, and the at least one check bit, so as to make the flash memory device determine whether an error occurs in the multiple bits of the parameter data according to the at least one check bit to generate a detection result bit, the multiple bits of the parameter data and the at least one check bit forming multiple bytes following the feature address;
wherein the processor further polls a status register of the flash memory device through the input/output circuit to obtain the detection result bit temporarily stored in the status register to determine whether an error occurs in an operation corresponding to the transmitted set-feature signal.

2. The flash memory controller of claim 1, wherein before generating and sending the set-feature signal to the flash memory device, the processor at first determines whether the feature address is associated with a change of a transmission mode; if the feature address is associated with the change of the transmission mode, the processor generates the at least one check bit to make the flash memory device determine whether an error occurs in the multiple bits of the parameter data when the transmission mode changes; and, if the feature address is not associated with the change of the transmission mode, the processor does not generate the at least one check bit, and the flash memory device does not determine whether the error occurs in the multiple bits of the parameter data.

3. The flash memory controller of claim 1, wherein when a result obtained from polling the detection result bit is that the set-feature operation is successful, the processor further sends an get-feature signal to the f flash memory device through the input/output circuit to control the flash memory device to report the multiple bits of the parameter data corresponding to the feature address, and determines whether an error occurs in an operation corresponding to the sent get-feature signal according to a result of whether a value indicated by the multiple bits of the reported parameter data conforms to an expected value range.

4. The flash memory controller of claim 3, wherein when the value indicated by the multiple bits of the reported parameter data conforms to the expected value range, the processor determines that a get-feature corresponding to the get-feature signal is successful and determines that the configuration of the feature address is correctly completed at this time; and, when the value indicated by the multiple bits of the reported parameter data does not conform to the expected value range, the processor determines that the get-feature signal corresponding to the get-feature signal fails, and sends the get-feature signal to the flash memory device again.

5. The flash memory controller of claim 1, wherein when a result obtained from polling the detection result bit is that the set-feature operation is successful, the processor further sends a get-feature signal to the flash memory device through the input/output circuit to control the flash memory device to report the multiple bits of the parameter data corresponding to the feature address, and determines whether an error occurs in an operation corresponding to the sent get-feature signal according to a content of at least one reserved bit among the multiple bits of the reported parameter data; when the at least one reserved bit is a default value, the processor determines that a get-feature signal corresponding to the get-feature signal is successful and determines that the configuration of the feature address is correctly completed at this time; and, when the at least one reserved bit is not the default value, the processor determines that the get-feature operation corresponding to the get-feature signal fails, and s sends the get-feature signal to the flash memory device again.

6. The flash memory controller of claim 1, wherein the set-feature signal in a default setting sequentially comprises the set-feature command, the feature address, and four data bytes; the at least one check bit is located at an end portion of a last one data byte of the four data bytes, and the multiple bits of the parameter data are located at the four data bytes' other portions except the end portion.

7. The flash memory controller of claim 1, wherein the set-feature signal in a default setting comprises the set-feature command, the feature address, and four data bytes; the at least one check bit indicates a check byte which is located in a last one data byte of the four data bytes, and the multiple bits of the parameter data are three parameter bytes and located in first three data bytes among the four data bytes; and, the check byte is generated by the processor performing the specific error correction protection operation based on a content of the three parameter bytes.

8. The flash memory controller of claim 1, wherein the set-feature signal in a default setting sequentially comprises the set-feature command, the feature address, and four data bytes; the at least one check bit indicates a check byte which is appended to an end of the four data bytes to form five bytes, and the multiple bytes of the parameter data are four parameter bytes and located in the four data bytes; and, the check byte is generated by the processor performing the specific error correction protection operation based on a content of the four parameter bytes.

9. The flash memory controller of claim 1, wherein the specific error correction protection operation is a logical exclusive-OR operation.

10. A method of a flash memory controller coupled to a flash memory device through a specific communication interface, comprising:
activating a configuration of a feature address of a set-feature operation of the flash memory device;
performing a specific error correction protection operation upon multiple bits of a parameter data corresponding to the set-feature operation to generate at least one check bit;
generating and transmitting a set-feature signal to the flash memory device, the set-feature signal sequentially comprising a set-feature command, the feature address, the multiple bits of the parameter data, and the at least one check bit, to make the flash memory device determine whether an error occurs in the multiple bits of the parameter data according to the at least one check bit to generate a detection result bit, the multiple bits of the parameter data and the at least one check bit forming multiple bytes following the feature address; and
polling a status register of the flash memory device to obtain the detection result bit temporarily stored in the status register to determine whether an error occurs in an operation corresponding to the transmitted set-feature signal.

11. The method of claim 10, further comprising:
before generating and sending the set-feature signal to the flash memory device, determining whether the feature address is associated with a change of a transmission mode;
if the feature address is associated with the change of the transmission mode, generating the at least one check bit to make the flash memory device determine whether an error occurs in the multiple bits of the parameter data when the transmission mode changes; and
if the feature address is not associated with the change of the transmission mode, not generating the at least one check bit, and controlling the flash memory device not to determine whether the error occurs in the multiple bits of the parameter data.

12. The method of claim 10, further comprising:
when a result obtained from polling the detection result bit is that the set-feature operation is successful, sending an get-feature signal to the flash memory device through the input/output circuit to control the flash memory device to report the multiple bits of the parameter data corresponding to the feature address; and
determining whether an error occurs in an operation corresponding to the sent get-feature signal according to a result of whether a value indicated by the multiple bits of the reported parameter data conforms to an expected value range.

13. The method of claim 12, further comprising:
when the value indicated by the multiple bits of the reported parameter data conforms to the expected value range, determining that a get-feature corresponding to the get-feature signal is successful and determining that the configuration of the feature address is correctly completed at this time; and
when the value indicated by the multiple bits of the reported parameter data does not conform to the expected value range, determining that the get-feature signal corresponding to the get-feature signal fails, and sending the get-feature signal to the flash memory device again.

14. The method of claim 10, further comprising:
when a result obtained from polling the detection result bit is that the set-feature operation is successful, sending a get-feature signal to the flash memory device through the input/output circuit to control the flash memory device to report the multiple bits of the parameter data corresponding to the feature address,
determining whether an error occurs in an operation corresponding to the sent get-feature signal according to a content of at least one reserved bit among the multiple bits of the reported parameter data;
when the at least one reserved bit is a default value, determining that a get-feature signal corresponding to the get-feature signal is successful and determining that the configuration of the feature address is correctly completed at this time; and
when the at least one reserved bit is not the default value, determining that the get-feature operation corresponding to the get-feature signal fails, and sending the get-feature signal to the flash memory device again.

15. The method of claim 10, wherein the set-feature signal in a default setting sequentially comprises the set-feature command, the feature address, and four data bytes; the at least one check bit is located at an end portion of a last one data byte of the four data bytes, and the multiple bits of the parameter data are located at the four data bytes' other portions except the end portion.

16. The method of claim 10, wherein the set-feature signal in a default setting comprises the set-feature command, the feature address, and four data bytes; the at least one check bit indicates a check byte which is located in a last one data byte of the four data bytes, and the multiple bits of the parameter data are three parameter bytes and located in first three data bytes among the four data bytes; and, the check byte is generated by the processor performing the specific error correction protection operation based on a content of the three parameter bytes.

17. A flash memory device, coupled to a flash memory controller through a specific communication interface, comprising:
an input/output control circuit, coupled to the flash memory controller through the specific communication interface;
a command register, coupled to the input/output control circuit, for buffering command information sent from the flash memory controller and transmitted through the input/output control circuit;
an address register, coupled to the input/output control circuit, for buffering address information sent by the flash memory controller and transmitted through the input/output control circuit;
a memory cell array, having a plurality of flash memory chips, each flash memory chip having a plurality of flash memory planes, each flash memory plane having a plurality of storage blocks, each storage block having a plurality of multiple storage pages;
at least one address decoder, coupled to the memory cell array;
a voltage generator, coupled between the at least one address decoder and the memory cell array, for generating and outputting at least one threshold voltage level to the at least one address decoder;
a control circuit, coupled to the address register, the command register, the voltage generator, and the memory cell array, for controlling the voltage generator to control the at least one address decoder to access a storage block of a flash memory chip of the memory cell array according to the at least one threshold voltage level; and
a status register, coupled to the input/output control circuit and the control circuit;
wherein when the flash memory device receives a set-feature signal, the control circuit is used to check and compare data of multiple bytes following a feature address of the set-feature signal to determine whether an error occurs in a set-feature operation corresponding to the set-feature signal to generate a detection result bit, and updates the detection result bit into the status register so that the flash memory controller then obtains the detection result bit by polling the status register.

18. The flash memory device of claim 17, wherein the control circuit further comprises:
a decision circuit, for receiving a feature command corresponding to the set-feature operation from the command register to determine whether the feature command is associated with a change of a transmission mode; and
a verification circuit, coupled to the decision circuit, for detecting and verifying whether an error occurs in data of the multiple bytes following the feature address of the set-feature signal when the feature command is associated with the change of the transmission mode;
when the feature command is not associated with the change of the transmission mode, the decision circuit is used to output the detection result bit, which indicates a successful result, into the status register; when it is determined that an error occurs in the data of the multiple bytes, the verification circuit is used to output the detection result bit, which indicates a failure result, into the status register; and, when it is determined that no errors occur in the data of the multiple bytes, the verification circuit is used to output the detection result bit, which indicates a successful result, into the status register.

19. The flash memory device of claim 18, wherein the verification circuit is used to perform a specific error correction protection operation upon multiple parameter bits in the multiple bytes to generate a result and to compare the result with at least one check bit following the multiple parameter bits to generate the detection result bit; when the result is matched with the at least one check bit, the verification circuit generates the detection result bit which indicates a successful result; and, when the result is not matched with the at least one check bit, the verification circuit generates the detection result bit which indicates a failure result.

20. The flash memory device of claim 19, wherein the verification circuit is used to compare a value of at least one reserved bit in the multiple parameter bits of the multiple bytes with a default value to update the detection result bit; when the value of the at least one reserved bit matches with the default value, the detection result bit updated by the verification circuit indicates a successful result; and, when the value of the at least one reserved bit does not match with the default value, the detection result bit updated by the verification circuit indicates a failure result.

21. The flash memory device of claim 19, wherein the verification circuit is used to determine whether at least one value specified by the multiple parameter bits of the multiple bytes is in an expected value range to update the detection result bit; when the at least one value is in the expected value range, the detection result bit updated by the verification circuit indicates a successful result; and, when the at least one value is not in the expected value range, the detection result bit updated by the verification circuit indicates a failure result.
